(19) United States
(12) Patent Application Publication
(10) Pub. No.: US 2011/0316337 A1
(43) Pub. Date: Dec. 29, 2011

(54) POWER GENERATION DATA CENTER

(76) Inventors: W. Leslie Pelio, Saratoga, CA (US); Jon N. Shank, San Francisco, CA (US)

(21) Appl. No.: 12/826,528

(22) Filed: Jun. 29, 2010

(51) Int. Cl. H02J 4/00

(52) U.S. Cl. 307/24

(57) ABSTRACT

A modular data center is collocated with a primary electric generating station and receives its operating power from connections upstream of any step-up transformer for transmission lines or grids. The data center itself comprises a building shell with a modular common power and cooling infrastructure to support data center containers brought in later by unrelated modular data center unit tenants. The heat and loads the data center containers each produce are isolated from the common areas and kept within the respective data center containers. The costs, maintenance, environmental, and security issues are therefore independent of the other modular data center unit tenants, and more easily managed, projected, and financed.

### BACKGROUND

1. Field of the Invention

The present invention relates to data centers located at a power generation source and connected to be powered from the primary generator at a point before the voltages are stepped up through transformers to the transmission and distribution utility grids.

2. Description of the Prior Art

Power generation stations were originally located very near the user locations because efficient transmission technologies did not exist. So in the beginning, large urban centers like New York's Manhattan District had several power generation stations that each occupied whole city blocks. Thomas Edison's installations used direct current (DC) connections to users and such limited practical transmission distances to a few hundred yards. Nikola Tesla succeeded in proposing alternating current (AC) transmission technologies and these allowed the power generating stations to be moved out of town by tens, and hundreds of miles away.

Generating Stations now include coal-fired, oil-fired, natural gas, hydro-electric, nuclear, wind farm, and solar energy types. Each of these has advantages and disadvantages in the fuels they require, the scale of power they can provide, the wastes they produce, the speed with which they can be cycled and modulated, and their dependencies on water, wind, and sunshine availability. So hydro-electric generators are located where the water of major rivers can be dammed, and wind generators are located in mountain passes where the prevailing winds funnel through. At the generating plants the energy is produced at a relatively low voltages, e.g., 2.3 kV and 30 kV. Together, the particular primary voltages they each produce can be synchronized and stepped up through large transformers to 138 kv, 230 kv, 345 kv, 500 kv, and 765 kv transmission lines interconnected into regional grids.

Big, heavy users of electrical power, such as aluminum smelting furnaces and other “transmission customers” can tap the power they need to operate directly from the transmission grid, e.g., at 138 kv or 230 kv. The transmission grid terminates at cities with substations and step downs to the local distribution grid. Primary customers receive stepped down voltages of 4 kv, and 13 kv, while sub-transmission customers can connect at 26 kv and 69 kv. Ordinary residential houses and small businesses are called secondary customers, and receive 120VAC and 240VAC stepped down from a transformer hanging on a pole right outside the user location. Big users have little choice in where they must locate themselves, so the cost of transmission is usually not a significant factor.

The Internet and other computer networks are supported by data center installations that house racks of network servers, data storage devices, network interfaces, power supplies, and cooling equipment. These buildings can run from less than 5,000 square feet to more than 50,000 square feet in floor area, and require all the usual designing, architecting, engineering, permitting, inspection, security, financing, tax reporting, and maintenance of real estate projects and industrial installations.

The simplest data center infrastructure is a Tier 1 data center, which is basically a server room, built using basic guidelines for the installation of computer systems. The most stringent level is a Tier 4 data center, which is designed to host mission critical computer systems, with fully redundant subsystems and compartmentalized security zones controlled, e.g., by biometric access controls methods. Subterranean data centers have been built recently to improve data security, environmental impacts, and cooling requirements.

There has been a tendency for States and municipalities to attract data centers to locate in their jurisdictions through tax incentives and cheap electrical power. For example, in 2010 Washington State passed a sales and use tax exemption that applies to server equipment, software, and electric infrastructure at eligible computer data centers in rural areas. A handful of data centers were already operating in Eastern Washington, which boasts cheap hydroelectric power and ample real estate. But in 2007, the State ruled that such data centers were not covered by a sales tax break meant for manufacturers.

At the other end of the spectrum is CoreSite's 1275 K Street data center located in downtown Washington, D.C., and is considered an accessible point of peering. It occupies over 20,000 square feet in a 230,000 square-foot building in the heart of Washington, D.C.'s central business district. CoreSite's 1275 K Street data center provides access to over fifty carriers and service providers with diverse fiber points of entry, rooftop line-of-site opportunities, and an on-site technician staff.

Amazon, eBay, and Google, are examples of companies who critically depend on very large data centers for their very existence. High systems availability, reliability, and security are very important. A $100 million data center construction that included Amazon was started in 2008 in Boardman, Oreg. Three large buildings were included, with the first one being 116,000 square feet. A new 10-megawatt power substation is being built nearby to support the data center. These data centers need an extraordinary amount of electrical power, and cooling.

The Columbia River basin has very large hydro-electric resources which enticed Google to build a huge data center in The Dalles, OR. Quincy, Wash., too was transformed from a small farming town into a large data center hub with new facilities from Microsoft and Yahoo.

A conventional data center includes raised floors for air ducts, cooling, power cabling, and data connections. Standardized 19″ RETMA racks are built above the floors and provide space for equipment chassis and cabinets. Cooling systems are needed to prevent overheating, and a typical data center will bring in very large amounts of utility power backed up with uninterruptable power supplies (UPS) and diesel generator systems. Redundant designs are used throughout to guarantee maximum up-time and reliability.

Transmitting electricity at high voltage reduces the fraction of energy lost to resistance. For a given amount of power, a higher voltage reduces the current and thus the resistive losses in the conductor. For example, raising the voltage by a factor of ten reduces the current by a corresponding factor of ten and therefore the I²R losses by a factor of one hundred, provided the same sized conductors are used in both cases. Even if the conductor size (cross-sectional area) is reduced ten-fold to match the lower current the I²R losses are still reduced ten-fold. Long distance transmission is typically done with overhead lines at voltages of 115 to 1,200 kV. At extremely high voltages of more than 2 MV, corona discharge losses exceed the benefits of lower resistance losses in the line conductors.

Transmission and distribution losses in the USA were estimated at 7.2% in 1995 and 6.5% in 2007. In general, losses are estimated from the discrepancy between energy produced (as reported by power plants) and energy sold to end customers. The difference between what is produced and what is consumed constitute transmission and distribution losses. As of 1980, the longest cost-effective distance for electricity was 7,000 km (4,300 ml), although all present transmission lines are considerably shorter.

In alternating current circuits, the inductance and capacitance of the phase conductors can be significant. The currents that flow in these components of the circuit impedance constitute reactive power, which transmits no energy to the load. Reactive current flow causes extra losses in the transmission circuit. The ratio of the real power transmitted to the load to the apparent power is the power factor. The more reactive current increases, the reactive power increases, and the power factor decreases. For systems with low power factors, losses will be higher than for systems with high power factors. So, utilities add capacitor banks and other components throughout the system to control reactive power flow to reduce losses and stabilize system voltage.

At the substations, transformers reduce the voltage to a lower level for distribution to commercial and residential users. This distribution is accomplished with a combination of sub-transmission (33 kV to 115 kV) and distribution (3.3 to 25 kV). Finally, the energy is transformed to low voltage at the point of use.

The extraordinary amount of electrical power, and cooling required by data centers can best be provided at the source of utility power generation. The running of microwave link and fiber optic cable connections is relatively trivial and easily accomplished, even when the data center is located at a very remote site.

### SUMMARY OF THE INVENTION

Briefly, embodiments of the present invention connect power generation sources directly to a collocated data center such that the power does not have to be stepped-up to transmission level and then stepped-down to distribution and end-users. The step-up/step-down process would otherwise result in power losses due to transmission and transformer inefficiencies. By avoiding that process, a higher percentage of the power produced by the generation source actually reaches critical load. Feeding electrical power directly into the data center from the power source eliminates transmission lines and other parts of the electrical grid. Such results in significant infrastructure savings. Essentially, each data center is placed at the power source and connected by fiber optic cables do its work with the Internet. The computer processing is done at the source of the power, and the fiber optic cables carry the information in and out from the network nodes. Each data center module is cooled in a way particular to the type of power generation source.

These and other objects and advantages of the present invention will no doubt become obvious to those of ordinary skill in the art after having read the following detailed description of the preferred embodiments which are illustrated in the various drawing figures.

### IN THE DRAWINGS

FIG. 1A is a functional block diagram of a large power grid showing the typical electrical power producers and users. A modular data center is shown collocated with and powered by a wind generator farm. Arrows by various step-up and step-down transformers indicate the usual one-directional or two-directional flow of power over time;

FIG. 1B is a functional block diagram of a large power grid like that of FIG. 1A, but with a modular data center shown collocated with and powered by a solar power;

FIG. 1C is a functional block diagram of a large power grid like that of FIG. 1A, but with a modular data center shown collocated with and powered by a coal plant;

FIG. 2 is a cut-away perspective view diagram of a flexible, just-in-time, modular data center embodiment of the present invention showing how containers are placed on various designated floor spaces and supported by a modular infrastructure;

FIG. 3 is a diagram of a method for constructing a flexible, just-in-time, modular data center embodiment of the present invention, selling and buying modular data center units, and installing a tenant's equipment;

FIG. 4 is a side view cutaway diagram of a flexible, just-in-time, modular data center embodiment of the present invention showing how each container isolates its cooling loads to corresponding chillers;

FIG. 5 is a functional block diagram of a data center collocated with a hydro-electric power plant, and connected to receive primary cooling from such power plant;

FIG. 6 is a functional block diagram of a data center collocated with an oil-fired power plant, and connected to receive primary cooling from such power plant;

FIG. 7 is a functional block diagram of a data center collocated with a gas-fired power plant, and connected to receive primary cooling from such power plant; and

FIG. 8 is a functional block diagram of a data center collocated with a nuclear power plant, and connected to receive primary cooling from such power plant.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF THE PREFERRED EMBODIMENT

The capital cost of electric power stations is so high, and electric demand is so variable, that it is often cheaper to import some part of the needed power rather than generate it locally. Nearby loads can be correlated, e.g., by hot weather which causes many users to switch on air conditioners. So imported electricity needs to come in from distant sources. Load balancing economics have caused wide area transmission grids to span out across whole countries and even large portions of continents. Many interconnections between power producers and consumers helps ensure that power can continue flow, even if a few links go down out of service.

The slowly varying portion of the electric demand is known as the base load, and is generally served best by large facilities with corresponding economies of scale, and low variable costs for fuel and operations. For example, nuclear, coal-fired power stations, and hydroelectric plants are good choices to supply base load requirements. Some renewable energy sources, such as concentrated solar thermal and geothermal power, can provide base load power. Other renewable energy sources, such as solar photo-voltaics, wind, wave, and tidal, by their nature can only add power to the grid independent of the demand, so other sources must be throttled up and down to keep the grid in balance. The variable part of the power demand can be filled in by peaking power plants which are smaller and faster-responding, but use higher cost energy sources. Combined cycle and combustion turbine plants fueled by natural gas are able to quickly respond to demand load changes.

Under ideal conditions, the long-distance transmission of electricity is cheap and efficient, with costs of $0.005 to $0.02 per kilowatt hour (kWh), compared to annual averaged large producer costs of $0.01 to $0.025 per kWh, and retail rates upwards of $0.10 per kWh, and far more for instantaneous suppliers at unpredicted highest demand moments. See, Wikipedia. Distant suppliers can be cheaper than local sources, which is why New York City buys a lot of electricity from Canada. But distant suppliers can be disconnected by bad weather and other disasters, so multiple local sources are necessary insurance, even if more expensive and infrequently used.

Long distance transmission also allows remote renewable energy resources to be used to displace fossil fuel consumption. The best hydro and wind locations are not usually near large cities and metropolitan areas. Solar costs are lowest in remote areas where users and the local power demand are minimal. Transmission and connection costs often determine whether a particular renewable energy generating station is economically viable.

Embodiments of the present invention collocate modular data centers, like those described by W. Leslie Pelio and Jon N. Shank in U.S. patent application, Ser. 12/712,598, filed Feb. 25, 2010, very near an energy generating station. In the case of a particular renewable energy generating station project that is only marginally viable due to transmission and connection costs, the collocation of a modular data center can transform the property into a money maker.

Some energy generating stations naturally cycle between full operation and zero, for example the daily cycles of a solar energy generating station that depend on sunshine. Others cycle with the wind, or demands from the grid. The collocation of a modular data center at these kinds of sites still makes economic sense because each energy generating station is inherently well connected to the transmission and distribution grids and can draw inexpensive power back through these facilities. In the case of a solar energy generating station, that reverse draw would be at night when rates are the lowest and power availability is at its best.

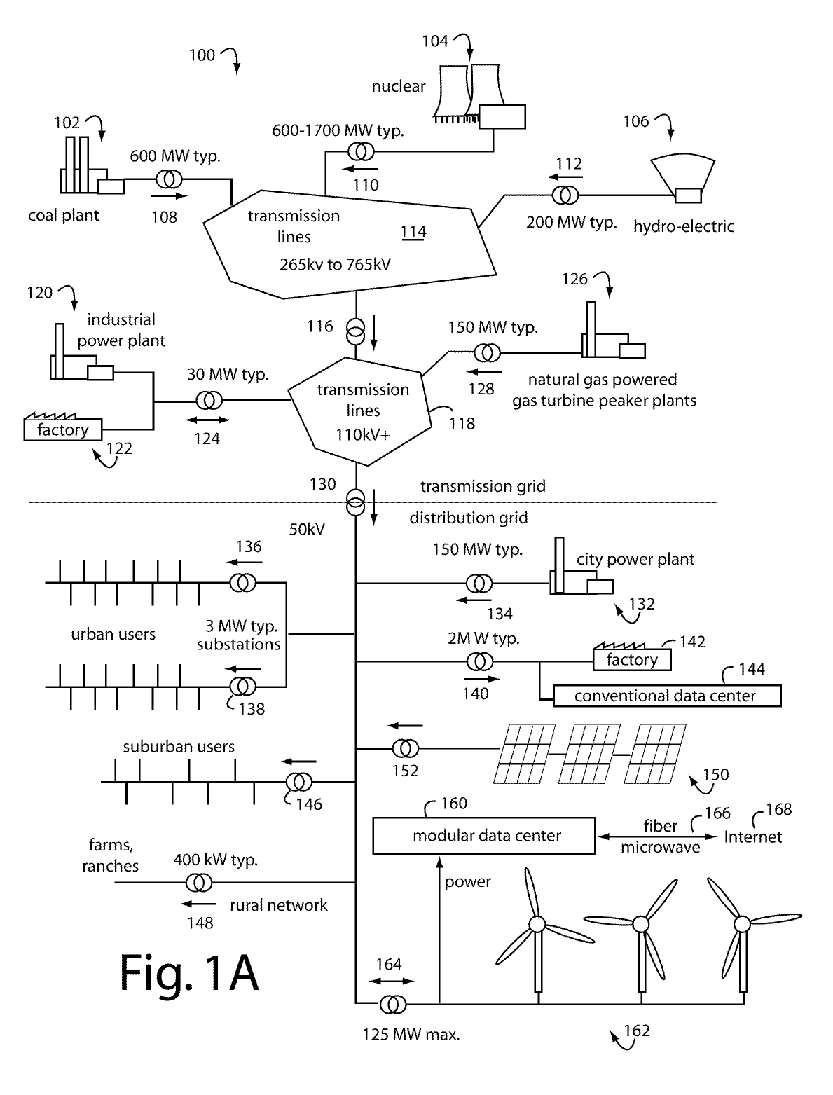

FIG. 1A represents a large power grid 100 showing the typical electrical power producers and users. For example, base load power is generated by a coal plant 102, a nuclear plant 104, and a hydro-electric station 106. These each employ step-up transformers 108, 110, and 112, that are necessary to raise the working voltages to the high levels needed by a transmission line system 114. (Arrows by various step-up and step-down transformers indicate the usual one-directional or two-directional flow of power over time.) Once the power generated has traveled most of the distance it needs to, it can be stepped down to a lower transmission grid voltage by a step-down transformer 116 for further routing by a transmission line system 118.

Each stepping up and stepping down of voltages with transformers, and hauling electrical power long distances over transmission lines involves power losses due to heating. In prior art installations of data centers these losses have been unavoidable.

An industrial power plant 120 can supply power locally to a factory 122 or to the transmission grid through a step-up transformer 124. A natural gas-powered gas-turbine peaker plant 126 supplies quick response power to the transmission grid through a step-up transformer 128. A step-down transformer 130 drops the transmission voltages down to 50 kV for local distribution. A city power plant 132 can supply spot or emergency power through a step-up transform 134 to the local distribution grid if the long distance transmission grid fails or is overtaxed. Urban users are supplied power from the local distribution grid through substation step-down transformers 136 and 138.

An industrial step-down transformer 140 supplies megawatts of power to users like factories 142 and conventional data centers 144. Suburban users receive their power through substation step-down transformers 146, and rural users through step-down transformers 148.

Conventional data center 144 has step-up transformers 108, 110, and 122, and step down transformers 116, 130, and 140 between it and the primary generating stations 102, 104, and 106. Power losses occur there as well as transmission line systems 114 and 118, and the local distribution grid.

A solar electric generating station 150 naturally produces direct current (DC) as high as 600 VDC which is then converted to alternating current (AC) with large inverters. The AC output can be connected to the distribution grid through a step-up transformer 152 or transmission line systems 114 or 118. In embodiments of the present invention, a collocated modular data center is primarily supplied the solar DC power before any inverter or step up transformer. At night, the modular data center would draw conventional AC power.

In FIG. 1A, a modular data center 160 is shown collocated with and powered by a wind generator farm 162. A step-up transformer 164 supplies power to the distribution and/or transmission grids when the wind is good, and draws power for the modular data center 160 at other times. A fiberoptic cable or microwave link 166 provides interconnectivity with the Internet 168 or other large computer data network.

In FIG. 1B, a modular data center 170 is shown collocated with and powered by solar electric generating station 150. The step-up transformer 152 supplies power to the distribution and/or transmission grids when the sun is good, and draws power for the modular data center 170 at other times. A fiberoptic cable or microwave link 176 provides interconnectivity with the Internet 178 or other large computer data network.

In FIG. 1C, a modular data center 180 is shown collocated with and powered by hydro electric generating station 106. The step-up transformer 112 supplies power to the distribution and/or transmission grids when the water supply is good, and draws power for the modular data center 180 at other times. A fiberoptic cable or microwave link 186 provides interconnectivity with the Internet 188 or other large computer data network.

The important common thread between FIGS. 1A-1C is that the modular data centers 160, 170, and 180 take their operating power directly from the electrical generating units before any corresponding step-up transformer.

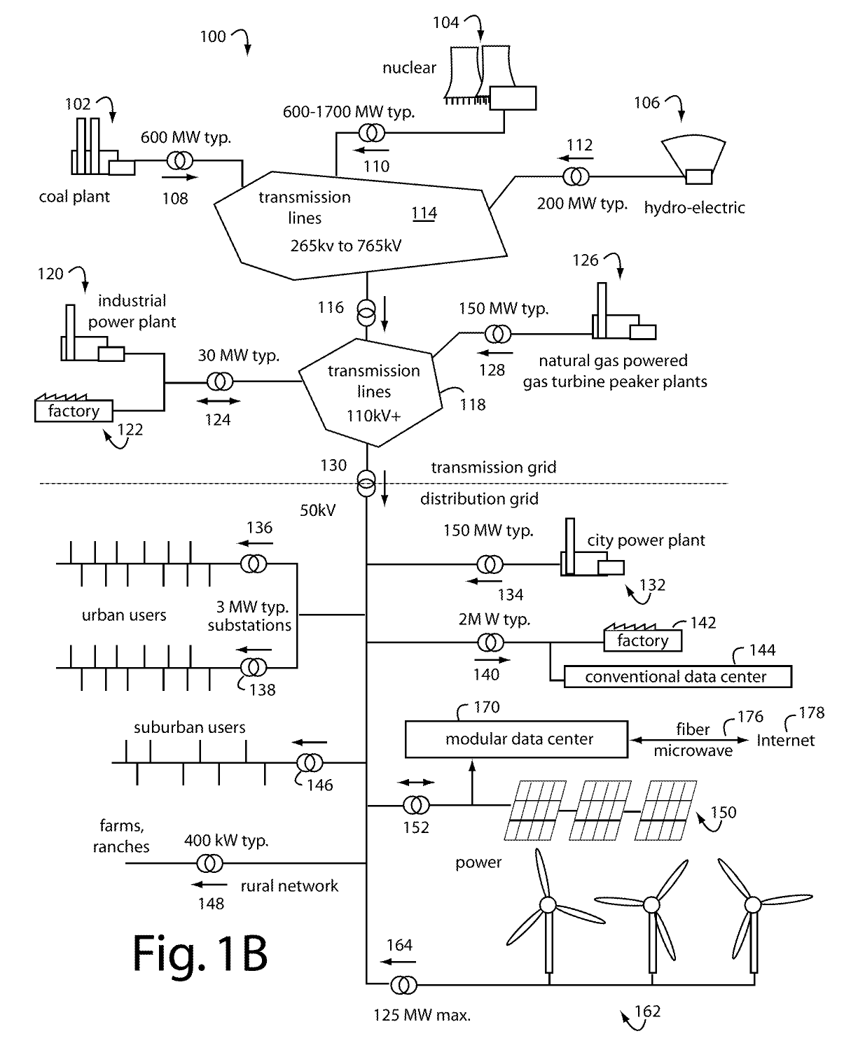

FIG. 2 represents a flexible, just-in-time, modular data center embodiment of the present invention, and is referred to herein by the general reference numeral 200. Such can be used in place of modular data centers 160, 170, and 180, in FIGS. 1A-1C. Flexible, just-in-time, modular data center 200 comprises a common building shell 202 partitioned into floor spaces, e.g., 204-109, designated for individual ownership and support of critical loads measurable in watts. Seismic enhancements to the common building shell 202 would be prudent in some areas and required in others, e.g., bracing, ties, reinforcements, anchoring, material upgrades, shear wall engineering, etc. A corresponding number of electro-mechanical adapters 214-119 are each situated at respective ones of the floor spaces 204-109. These provide for the placement, connection, and operation of modular containerized data centers as critical loads. Such containers can be ordered from their manufacturers fully provisioned with the servers already installed.

In FIG. 2, two such containers 224A and 225B are shown stacked together on one floor space 204, and a third data center container 225 is in the next group of floor spaces. Although FIG. 2 shows them as foundation rings on top of the floor, the electro-mechanical adapters 214-219 could be entirely overhead, e.g., comprising electrical cable raceways like 230, and roof-top cooling (HVAC) units like 232 and 234. This arrangement provides for defensible spaces and security inside and between the containers, and puts all the servers in respective isolated environments. Each container can have its own key-access system, so the physical security at a modular data center need not be as intense as in a conventional data center.

Various sizes of containers can be accommodated, e.g., ISO-Standard 20, 40, and 53-foot length types. These are floated-in through large roll-up back doors 235 and 236 at the end of shipping docks and ramps, e.g., using an air-bearing pontoon system for shipping containers, as described in U.S. Pat. No. 6,164,229, issued 22/26/2000, to Richard Cavanaugh. The floor is sized and finished to serve as a float platform 237. Alternatively, a standard crane system can be used.

A number of modular power supply systems 240-143 are disposed behind the common building shell and provide for the operating power predetermined for the particular modular containerized data centers then or soon to be resident. For example, these can be full UPS systems with batteries, generators only, and/or utility sub-panels and transformers. Each data center container may alternatively obtain its power directly from the utility via a switchgear, transformer and conduit system. Any generator would be used for a back-up and power the critical load only in the event of an outage. It would not typically be a primary source.

A corresponding number of modular cooling systems, like HVAC units 232 and 234 or shipping containers, are disposed in the common building shell and provide for the cooling predetermined for the particular modular containerized data centers then or soon to be resident. Common cooling can be augmented by individual users to increase the range of the common system.

Data connections are disposed throughout the common building shell and provide for network connectivity. Raceway 230 is one example of how these can be implemented.

Standard piping and conduit can be used to deliver the cooling, power, and data connectivity.

The conventional way of taking on a whole new data center in one big bite does not accommodate efficient use of customer resources. It is not easy for clients to make good use of so much critical load capability when they first take possession. It would be much more advantageous for a client to buy only the critical load they need now, and then be able to incrementally buy additional critical load as needed. For example, container-by-container, rather than having to commit to building and equipping a complete whole data center estimated to have the capabilities forecast as necessary during its life.

Traditional data centers were built having large, open rooms that necessitated cooling air to flow relatively long distances to cool the servers and then be exhausted from the room. It is more efficient for the rooms to be smaller, like a container, in order to localize the cooling and thus reduce the size of the cooling units. Each facility should be equipped with all the connections and ducting necessary for intensive use of the data center container.

Conventional data centers do not incorporate new technologies very easily. Data center embodiments of the present invention allow improvements in efficiency as new technologies are introduced to the marketplace.

Conventional multi-tenant collocation facilities have thwarted the usual efficiencies that individual users can realize, because they used a shared infrastructure. The data center container layout embodiments allow many users to share space and collect the benefits of having their own facility. They can control their efficiencies themselves. Modular data centers can be leased or purchased by collocation companies and then subleased to their clients.

Each data center must have adequate access to power, water, and connectivity, and an overall plan is needed to merge all these together in a cohesive way. The modules and containers themselves do not make a data center operational. The entire package must be assembled for it to be functional and scalable. Air-cooled chillers do not necessarily work for every application and might have some California Code of Regulations, Title 24.

Data center embodiments of the present invention can evolve with developing technology. State-of-the-art designs can be implemented as soon as new technology becomes available. Modular units may not always need the typical enclosures. For example, if air flow for cooling is not required because liquid cooling of the processor is used, then a cabinet enclosure may not be necessary. Some type of fencing system may be more appropriate.

Data center embodiments of the present invention can be stratified to handle multiple applications at one site, e.g., UPS-only, N, N+1 and 2N redundancies all in the same building. The result is that each client can have their best, most cost-effective configuration.

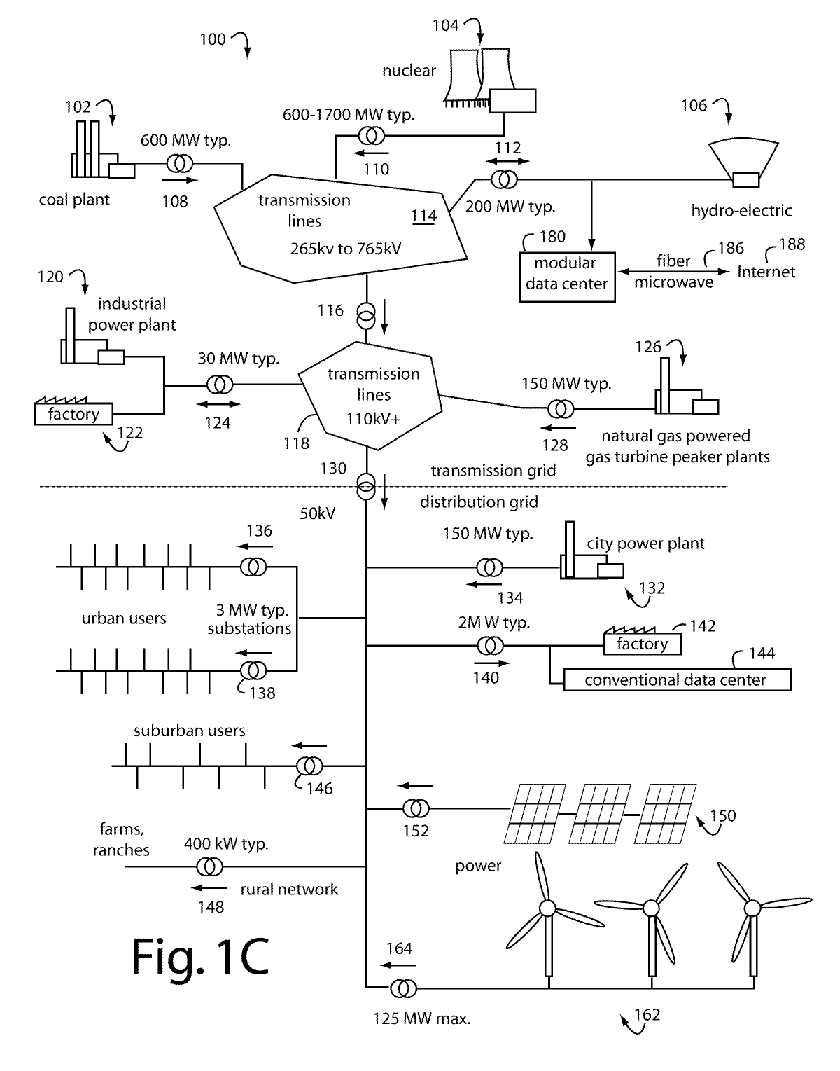

FIG. 3 represents a flexible, just-in-time, modular data center construction and operation process 300 in accordance with the present invention. A developer builds a shell 302 by acquiring the land and financing in a step 304. The shell is architected and engineered in a step 306 which does not include any conventional servers or racks.

Step 306 includes the architecture, such as the layout and details for walls, ceilings, floors and glazing, wall sections and elevations, ceiling plan layout including light fixtures, and general construction project elements. The mechanical systems include details, drawings and specifications for heating, ventilating and air conditioning (HVAC) systems, fresh air requirements per local codes, piping and ductwork routing, and equipment specification, locations and schedules. The electrical systems engineering includes drawings and specifications for electrical equipment, location, schedules, one-line diagrams and details, including any emergency generator systems, specifications, design, and detail of feeder and branch circuitry, layout of general and emergency lighting. Fire protection and suppression systems engineering includes details, drawings and specifications for fire alarm, detection and suppression systems, piping routing, schedules and one-line diagrams.

The building permits are obtained in a step 308 and the process is highly simplified by not having to include any conventional servers or racks, nor the full complement of infrastructure the shell could ultimately house and require. Permits for containers can be approved once and then additional containers can be installed under the same permit. The cost of, reserving growth space is minimized due to demand driven deployment of capital intense equipment.

A simplified shell construction proceeds in a step 310. Building permit approvals and occupancy are therefore quicker and easier to obtain in a step 312 than in conventional data center construction. A modular data center 314 is thus ready to offer modular data center unit ownership and tenancies in a step 316. As these occupants move in, a step 318 negotiates with them to install the add-on additional electrical and mechanical infrastructure that the new modular data center unit will need.

One or more data center users can buy-in and/or operate a tenancy of one or more data center containers 320 of theirs to be placed in modular data center 314. Each data center container 320 is factory-built offsite, e.g., by IBM, HP, SGI/Rackable, etc. These are separately designed, built, tested, and certified in steps 322, 324, 326, and 328. The data center users can purchase a modular data center unit or lease one in a step 330. The occupants' data center containers 320 are installed in a step 332 and the add-on infrastructure of step 318 is sized according to the new occupants' specifications for redundancy, operating margins and efficiency.

Each new data center container 320 is installed independent of any others, and can be commissioned in a step 334 without affecting any other tenants. The data center containers 320 are placed on-line in a step 336, and is the respective data center users that must provide their own unit security, operation, and maintenance in a step 338. Common area security, operation, and maintenance are provided by the tenant or operator of modular data center 314.

Data center container 320 can be easily replaced anytime in the future if it breaks down or becomes obsolete. By the same token, other owners and users can place their own data center containers 320 into modular data center 314 if free space is still available.

A method of modular data center ownership of a data center would comprise writing a master deed legally defining individual and common ownership of a flexible, just-in-time, modular data center. Then, a plurality of modular data center units would be built in the flexible, just-in-time, modular data center that can be owned or leased by individual owners and rented to independent tenants.

Referring again to FIG. 2, data center 200 comprises a building shell 202 into which can be installed many data center containers, e.g., 204-209. Such containers provide tremendous equipment configuration flexibility in the overall design. Different equipment support packages can be included in each one, depending on the applications running on the servers. Each container user can specify their own “equipment heat tolerance,” allowing for increased efficiencies and reduced operational costs.

In spite of the example of FIG. 2, a typical flexible, just-in-time, modular data center can occupy one or more rooms of a building, one or more floors, or an entire building. Inside, the data center containers themselves, most of the equipment comprises network servers mounted in nineteen-inch rack cabinets, and those are organized into single rows with corridors in between to allow access to the front and rear of each cabinet. The servers can differ greatly in size from servers one rack unit (1U) tall (1.75″), to large freestanding storage silos that occupy a floor area of many square tiles. Some equipment, such as mainframe computers and storage devices, are often as big as the racks themselves, and are placed alongside. Very large data centers can use standard-size shipping containers home to 1,000 or more servers each. When repairs or upgrades are needed, it is often more cost effective to replace the whole container, rather than trying to fix the individual servers within.

Referring again to FIG. 2, the building shell 202 comprises, in general, a concrete slab floor with a concrete, tilt-up perimeter wall, and a roof supported by steel girders and columns. Local building codes may govern the minimum ceiling heights inside building shell 202. Some or all of the data center containers may be installed immediately, or none at all. Tenants may be required to sign contracts after the building shell 202 is complete and local government building department has approved it to be occupied and used. The data center containers that these tenants need can be ordered, installed, and commissioned in very quick order. The building shell 202 provides all the power, cooling, and network connectivity needed.

The physical environments of data centers need to be carefully controlled, especially inside each container. Air conditioning is used to limit the environmental temperatures and the humidity. A temperature range of 18-27° C. (64-81° F.), and a humidity range of 40-55% with a maximum dew point of 15° C. is considered optimal for data center conditions.

The temperature tolerances in newer equipment are increasing, and therefore the optimal environmental temperatures are changing as well. The temperature set-points are modifiable to suit the newer temperature tolerant designs.

The electrical power consumed by the servers and data storage units can be quite considerable. They therefore can be expected to generate a lot of heat, and overheating can cause serious equipment failures. By controlling the air temperature, the server components at the board level are kept within the manufacturer's specified temperature/humidity range.

Air conditioning systems help control humidity by cooling the return space air to below the dew point. Liquid water can otherwise condense on the internal components. In case of a dry atmosphere, ancillary humidification systems may add water vapor if the humidity is too low, which can result in static electricity discharge problems which may damage components. Subterranean data centers are possible, and can be an inexpensive way to keep computer equipment cool compared to conventional designs.

Some data centers use naturally cool outside air as a coolant. In Washington State, it's practical to use the outside air as a natural coolant eleven months of the year. The chillers/air conditioners are only needed one twelfth of the year, for an energy savings that can be in the millions of dollars.

Backup power is one way so-called N+1 redundancy in the systems can be implemented. Uninterruptible power supplies (UPS) with batteries, and diesel generators are used to keep the flexible, just-in-time, modular data center up when the utility power goes down. Cloud computing installations may not need this kind of backup power N+1 redundancy because other nodes in the “Cloud” can automatically assume the workloads.

Single point failure prevention requires that all elements of the electrical systems, including backup system, be fully duplicated. And critical servers are connected to both the “A-side” and “B-side” power feeds. This arrangement realizes an N+1 Redundancy in the systems. Static switches are sometimes used to ensure instantaneous switchover from one supply to the other in the event of a power failure.

Whole data centers, and especially the containers themselves, typically incorporate fire protection systems, including passive and active design elements, as well as implementation of fire prevention programs in operations. Smoke detectors are usually installed to provide early warning of a developing fire by detecting particles generated by smoldering components prior to the development of flame. This allows investigation, interruption of power, and manual fire suppression using hand held fire extinguishers before the fire grows to a large size. A fire sprinkler system is often provided to control a full scale fire if it develops. Clean agent fire suppression gaseous systems are sometimes installed to suppress a fire earlier than the fire sprinkler system. Passive fire protection elements include the installation of fire walls around the data center, so a fire can be restricted to a portion of the facility for a limited time in the event of the failure of the active fire protection systems, or if they are not installed.

Physical security is such that physical access to the site is restricted to selected personnel, with controls including bollards and mantraps. Video camera surveillance and permanent security guards are almost always present if the data center is large or contains sensitive information on any of the systems within. The use of finger print recognition man traps is now commonplace.

Communications in data centers are based on Internet Protocol networks. Data center routers and switches transport traffic between servers and to the outside world. Redundancy of the Internet connection is often provided by using two or more upstream service providers, e.g., multihoming. Some servers in data centers are used for basic Internet and intranet services needed by internal users in the organization, e.g., e-mail servers, proxy servers, and DNS servers.

Network security usually includes firewalls, VPN gateways, intrusion detection systems, etc. Also common are monitoring systems for the network and some of the applications. Additional off site monitoring systems are also typical, in case of a failure of communications inside the data center.

A main purpose of data centers is to support the core business and operational data applications of organizations. Common applications are Enterprise Resource Planning (ERP) and Customer Relationship Management (CRM) web application systems. A data center may be limited to operations architecture, or it may provide other services as well. These applications may have multiple hosts, each running a single component. Common components include databases, file servers, application servers, middleware, etc.

Data centers are also used for off-site backups. Companies may subscribe to backup services provided by a data center, e.g., to backup tapes. Backups can be taken off local servers and on to tapes. However, tapes stored on site are a security risk, and can be damaged by fire and flooding. Larger companies send their backups off-site to reduce the risk of common disasters. Encrypted backups are sent safely over the Internet to another data center where they can be stored securely.

Intermodal and freight shipping containers are reusable transport and storage units for moving products and raw materials between locations or countries. The containers manufactured to International Organization for Standardization ISO specifications are ISO containers, and high-cube containers that the same only taller than normal. There are at least seventeen million intermodal containers moving around in the world, and a large part of the world international trade is transported by shipping container.

The containerization system developed from 8-foot cube units used by the United States military that was later standardized in 10-foot, 20-foot, and 40-foot lengths. The longer, higher and wider variants are now in general use. Container variants are available for many different cargo types. An air freight alternative is lighter and IATA defined as a Unit Load Device. Such may also one day be used as a data center container.

A typical container has doors on one end, and is constructed of corrugated weathering steel. Containers were originally 8 feet wide by 8 feet high, and either twenty or forty feet long. They can be stacked up to seven units high. Taller units include high-cube units that are 9′6″ and 10′6″ tall. In the United States, longer units are common that are 48 feet and 53 feet in length.

Lighter swap body units use the same mounting fixings as Intermodal containers, but have folding legs under their frames so that they can be moved between trucks without using a crane. Each container is given a standardized ISO 6346 reporting mark (ownership code), four characters long ending in either U, J or Z, followed by six numbers and a check digit.

Container capacity is often expressed in twenty-foot equivalent units (TEU). An equivalent unit is a measure of containerized cargo capacity equal to one standard 20 feet (length)×8 feet (width) container. As this is an approximate measure, the height of the box is not considered; for example, the 9 feet 6 inch (2.90 m) high cube and the 4-foot-3-inch (1.30 m) half height 20-foot (6.10 m) containers are also called one TEU. Similarly, the 45 feet (13.72 m) containers are also commonly designated as two TEU, although they are 45 and not 40 feet (12.19 m) long. Two TEU are equivalent to one forty-foot equivalent unit (FEU).

High reliability data centers include matching uninterruptible power supply (UPS) systems, e.g., 140-143 (FIG. 1) to guarantee power to the critical loads. Typically, critical loads are served by online UPS that may be paralleled together for increased capacity or redundancy, or both. In a Tier Four facility, a fault tolerant site infrastructure guaranteeing 99.995% availability, the UPS systems may be arranged in a 2N configuration to ensure UPS power always reaches the critical load.

When matching a facility's desired reliability to the business' actual requirements, the tenant will estimate a dollar amount per minute or hour that unplanned downtime will cost the firm. This amount is then considered against the costs of designing and constructing a facility of sufficient reliability to minimize the risk of this happening. Typically this cost includes facility construction and equipment cost, design costs, and occasionally maintenance costs. One cost that is not always considered, however, is the cost of efficiency of the UPS system itself.

Static UPS systems have efficiency ratings, which are a measure how much of the input electricity is actually available to the load after the overhead incurred by system electronics, power conversion and so forth. These efficiency ratings usually range from around 92% to 95%. Certain systems may be able to achieve efficiency ratings of up to 97% at or near full load. The issue of UPS efficiency can be broken down into different UPS have different efficiencies, and the same UPS has a different efficiency at a different load level.

The critical loads for a data center are divisible into three categories: vital, essential, and non-essential. Vital loads support 24/7 vital data processing equipment, service providers, and imperative call services that cannot be interrupted. Essential loads support mechanical units, motors and pumps, refrigeration units, and lighting that can be momentarily interrupted. Non-essential loads support work stations, supplementary equipment, and general area mechanical support that can be interrupted without significant detriment.

In general, the use of containers in flexible, just-in-time, modular data centers of the present invention allows tremendous flexibility in the configuration and design of the other equipment needed to support such containers. Each can be supported with different levels of redundancy, and with wide or very thin engineering margins. For example, each individual container user can specify their own levels of equipment heat tolerance, which balances equipment life and failure risk, with expected capital and operating expenses.

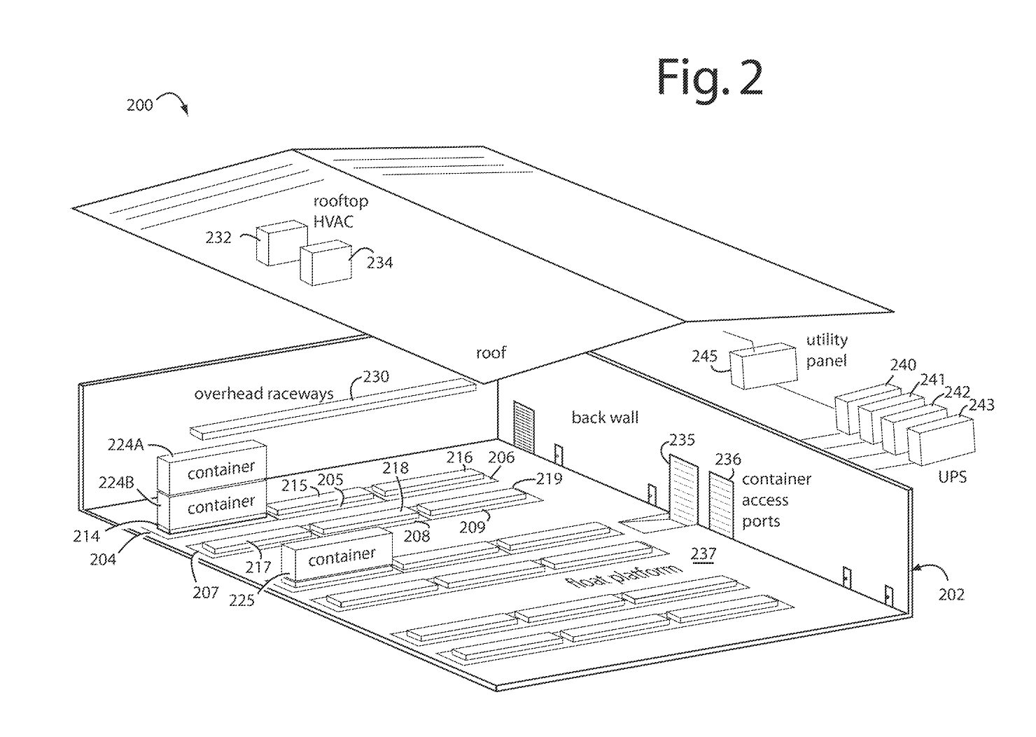

FIG. 4 represents a flexible, just-in-time, modular data center embodiment of the present invention, and is referred to herein by the general reference numeral 400. The flexible, just-in-time, modular data center 400 comprises a common building shell 402 with a common room air volume 404 inside between front and back walls 406 and 408.

A number of data center containers 410-412 on a floor 414 are individually cooled by refrigeration type roof-top cooler units 420-422 on a roof 424 connected by drop-down chilled water hoses 431-436.

Alternatively, air cooling towers located on the roof or in the back of the building can be used. Each roof-top cooler unit 420-422 concerns itself only with its respective data center container 410-412, and is not burdened with cooling the common room air volume 404. This configuration is far more efficient than conventional data center designs with raised floors that need to cool the entire interior volume of the whole building.

An overhead raceway 440 provides for data fiber connectivity and electrical power connections to uninterruptable power supply (UPS) unit 442 and utility power. Each data center container 410-412 can easily require six hundred kilowatts of power from a 2-megawatt generator in another container, and the consequential 200-ton cooling demands of using that much power.

These modular data centers can take advantage of the sites in which they are located to help with cooling or with making use of what would otherwise be waste heat.

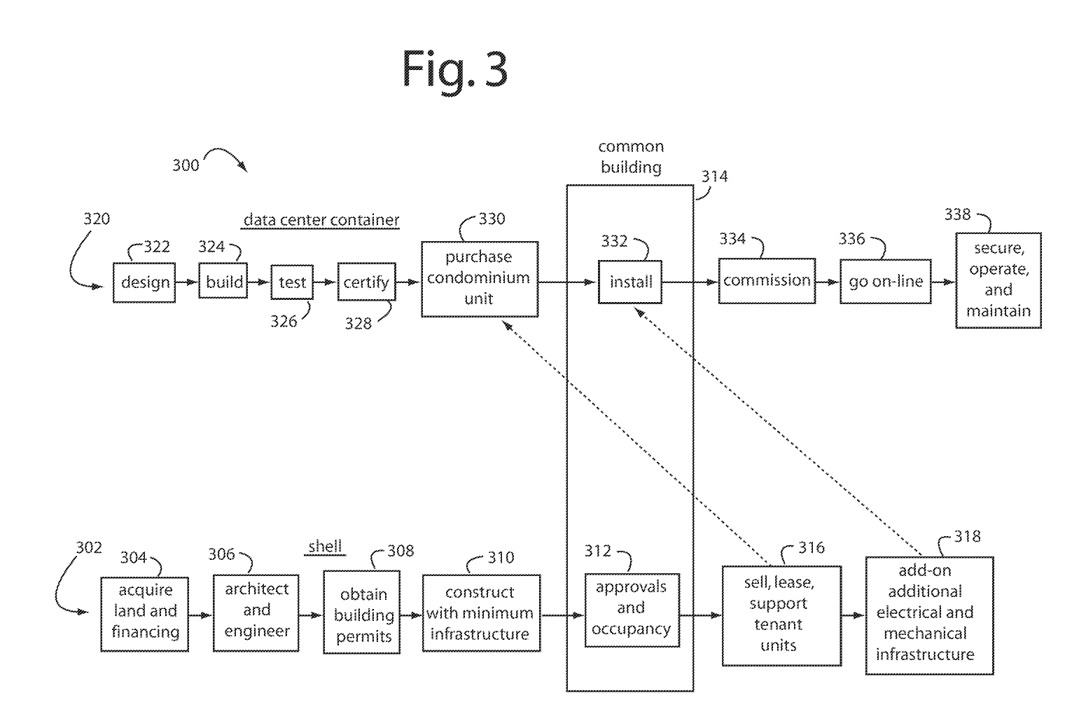

FIG. 5 represents a configuration 500 in which a modular data center 502 has been collocated with a hydro-electric power plant 504. The modular data center 502 receives its operating power at the primary voltage from a power tap 506 before the plant's output is stepped up to transmission line voltages by a step-up transformer 508. Data center cooling is provided by a heat exchanger 510 through which the hydro effluent passes on its way to an afterbay or tailrace.

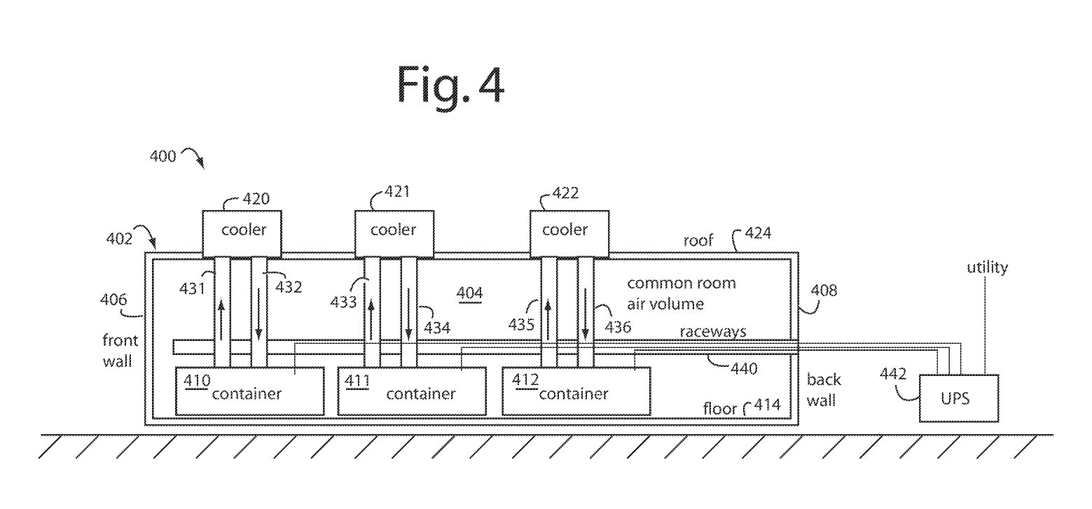

FIG. 6 represents a configuration 600 in which a modular data center 602 has been collocated with an oil-fired power plant 604. The modular data center 602 receives its operating power at the primary voltage from a power tap 606 before the plant's output is stepped up to transmission line voltages by a step-up transformer 608. The generator voltage ranges from 11 kV in smaller units to 22 kV in larger units. Data center cooling is provided by a heat exchanger 610 through which the oil fuel is fed.

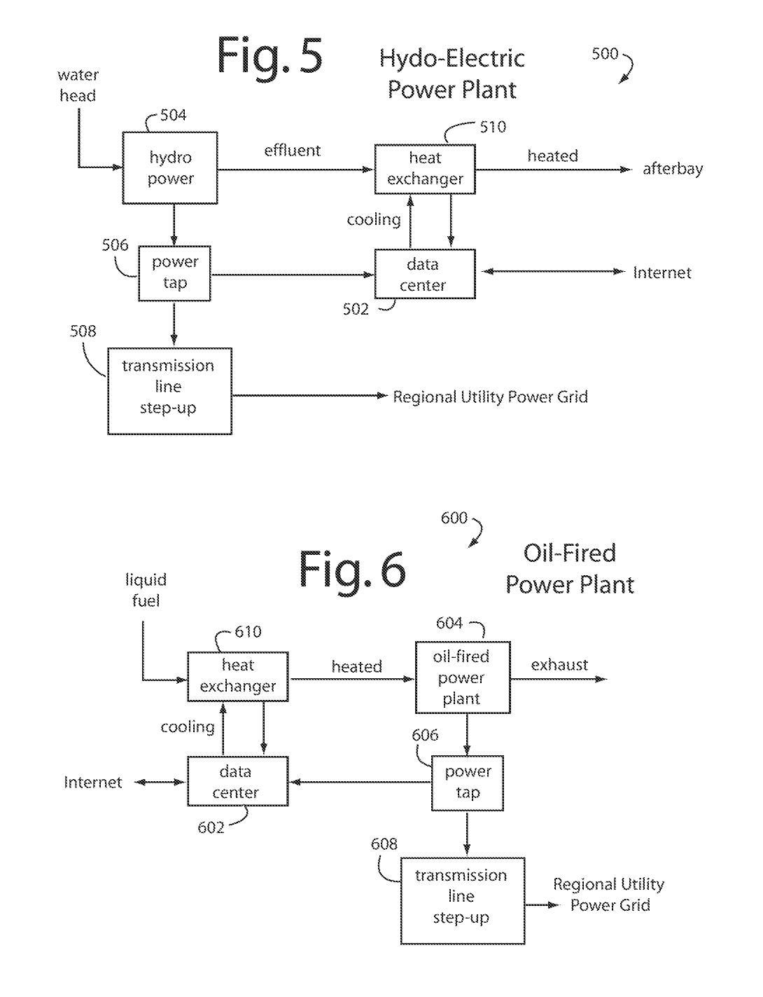

FIG. 7 represents a configuration 700 in which a modular data center 702 has been collocated with a gas-fired power plant 704. The modular data center 702 receives its operating power at the primary voltage from a power tap 706 before the plant's output is stepped up to transmission line voltages by a step-up transformer 708. Data center cooling is provided by a heat exchanger 710 through which the oil fuel is fed.

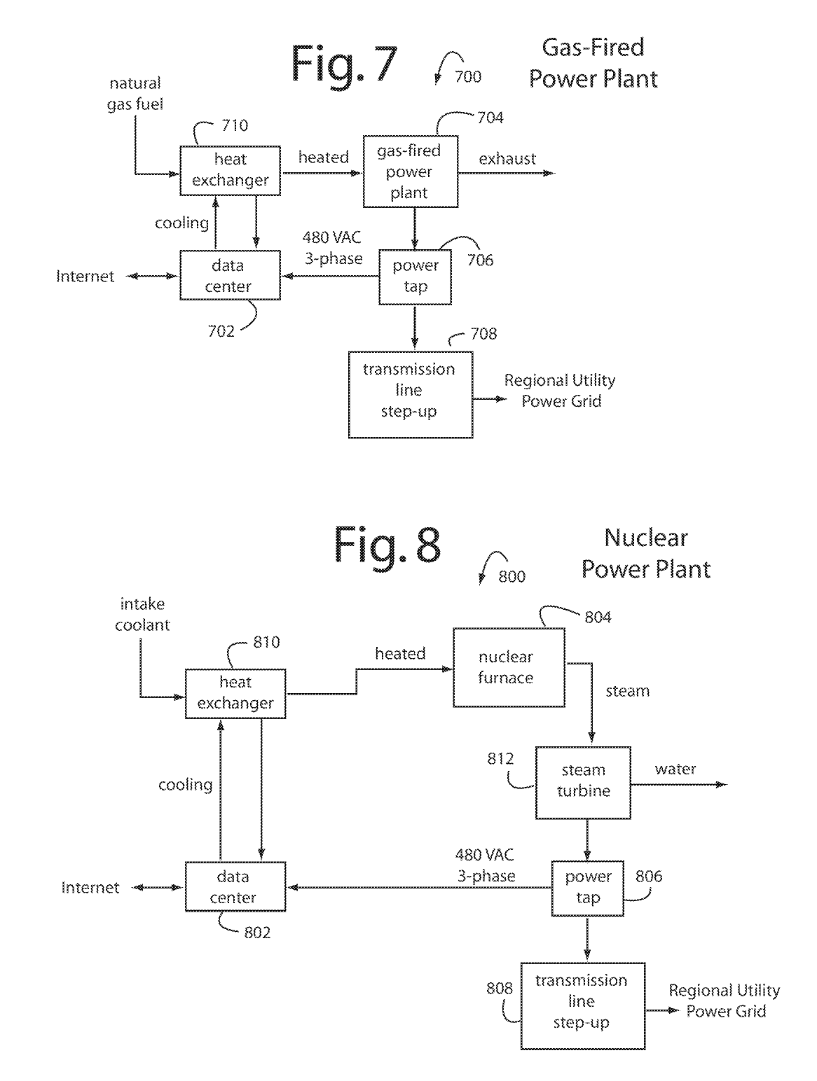

FIG. 8 represents a configuration 800 in which a modular data center 802 has been collocated with a nuclear power plant 804. The modular data center 802 receives its operating power at the primary voltage from a power tap 806 before the plant's output is stepped up to transmission line voltages by a step-up transformer 808. Data center cooling is provided by a heat exchanger 810 through which an intake coolant passes on to the nuclear power plant 804 and a steam turbine 812. Heat from the data center 802 helps the nuclear power plant 804 raise the feed-water to an operational steam. After the steam passes through the turbine 812, the steam is typically condensed in a condenser and recycled to where it was heated, e.g., the so-called Rankine cycle.

In general, the data centers (160, 170, 180, 200, 300, 400, 502, 602, 702, and 802) collocated with a corresponding electric generating plant would include a power connection tap placed on the primary winding side of any local step-up transformer for a transmission line and grid, with such tap providing an input for critical load voltages of 2.3 kV to 30 kV and 2-4 MW of power. When the local corresponding electric generating plant is not operational, then such tap provides a backfeed down from the transmission line and grid to keep the data center operational. Primary cooling may be interrupted as well, so a secondary cooling system would typically need to be included.

Alternatively, a cloud network architecture in the Internet could be relied upon to seamlessly assume the data center jobs that would be dropped when a local data center's electric generating plant went down due to lack of fuel, sun, wind, gas, or demand.

Although the present invention has been described in terms of the presently preferred embodiments, it is to be understood that the disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the “true” spirit and scope of the invention.

What is claimed is:

1. A modular data center, comprising:
an electrical power tap for connection to a collocated power generating station, and connected on the primary side of a local step-up transformer for a transmission line and grid, and providing a critical load voltage input of 2.3 kV to 30 kV;
a common building shell partitioned into floor spaces designated for individual control and support of critical loads measurable in watts;
a plurality of electro-mechanical adapters each situated at corresponding ones of said floor spaces, and providing for the placement, connection, and operation of modular containerized data centers as critical loads;
a plurality of power supply systems having power input connections to the electrical power tap, and disposed in the common building shell, and providing for critical load operating power predetermined for particular modular containerized data centers;
a plurality of cooling systems disposed in the common building shell and providing for the cooling predetermined for particular modular containerized data centers;
a plurality of data connections disposed in the common building shell and providing for the network connectivity predetermined for particular modular containerized data centers; and
an Internet connection comprising at least fiberoptic cables or microwave radio links, and interfaced to the plurality of data connections.

2. The modular data center of claim 1, wherein a cloud network architecture is relied upon to seamlessly assume any data center jobs that would be dropped when said collocated power generating plant went down due to lack of fuel, sun, wind, gas, or demand.

3. The modular data center of claim 1, wherein said collocated power generating plant is a solar electric type, and the power connection tap can draw operating power for the data center through said local step-up transformer from said transmission line and grid.

4. The modular data center of claim 1, wherein said collocated power generating plant is a wind powered electric type, and the power connection tap can draw operating power for the data center through said local step-up transformer from said transmission line and grid.

5. The modular data center of claim 1, wherein said collocated power generating plant is a hydro-electric type, and the power connection tap can draw operating power for the data center through said local step-up transformer from said transmission line and grid.

6. The modular data center of claim 1, wherein said collocated power generating plant provides primary cooling for the data center.

7. A collocated power generator and data center, comprising:
a power generating station having voltage step-up transformers and connections to a transmission or distribution line or grid;
a data center collocated near enough to the power generator station so as to avoid the use of high voltage transmission and distribution lines and grids exceeding 30 kV, and having a power input connection for critical loads from a tap at the power generating station before any voltage step-up transformer;
a plurality of data connections disposed in the data center and providing for network connectivity predetermined for particular modular containerized data centers; and
an Internet connection comprising at least fiberoptic cables or microwave radio links, and interfaced to the plurality of data connections;
wherein, step-up and step-down transformer losses and transmission and distribution grid energy losses are avoided in the powering of the data center collocated with the power generating station.

8. A collocated solar power generator and data center, comprising:
a solar power generating station primarily producing direct current power that is converted to alternating current by inverters for voltage stepping up with transformers to a transmission or distribution line or grid;
a data center collocated with the solar power generator station and receiving said direct current power as its primary operating power without any intermediate conversion by said inverters and transformers;
a plurality of data connections disposed in the data center and providing for network connectivity predetermined for particular modular containerized data centers; and
an Internet connection comprising at least fiber optic cables or microwave radio links, and interfaced to the plurality of data connections;
wherein, substantial transmission and distribution grid energy losses are avoided in the powering of the data center collocated with the solar power generating station.
